(19) United States
(12) Patent Application Publication
(10) Pub. No.: US 2024/0222126 A1
(43) Pub. Date: Jul. 4, 2024

(54) FABRICATION OF NOVEL DEVICES USING ION BEAMS

(71) Applicant: Intel Corporation, Santa Clara, CA (US)

(72) Inventors: Mahmut Sami Kavrik, Eugene, OR (US); Uygar Avci, Portland (CA); Brandon Holybee, Portland, OR (US); Jennifer Lux, Hillsboro, OR (US); Kevin O'Brien, Portland, OR (US); Shida Tan, Saratoga, CA (US)

(21) Appl. No.: 18/147,644

(22) Filed: Dec. 28, 2022

(51) Int. Cl. H01L 21/266; H01L 21/265

(52) U.S. Cl. CPC H01L 21/266; H01L 21/26506

(57) ABSTRACT

This disclosure describes systems, apparatus, methods, and devices related to fabrication using ion beams. The device may apply an ion beam targeted to at least one of one or more regions of a top layer, a metal layer placed on top of the top layer, or one or more ion stoppers placed on top of the top layer, wherein the ion beam is tuned using a predetermined energy range or a dosing level of ions to modify the material characteristics of the 2D material at the one or more regions of the top layer. The device may create a bond between the one or more 2D and metal layers to the one or more regions of the top layer where the material characteristics of the 2D material have been modified due to the impinging ion beam.

### TECHNICAL FIELD

This disclosure generally relates to systems, apparatus, and methods for the fabrication of devices and, more particularly, to the fabrication of novel devices using ion beams.

### BACKGROUND

Traditional scaling in silicon-based transistors is becoming less common due to physical limitations. 2D materials specifically transition metal dichalcogenide (TMD) may be a silicon replacement in a transistor. However, implementation of TMDs into next-generation transistors is precluded due to high contact resistance between metals and TMDs. In addition, the absence of a viable process to form n and p-type channels from TMDs are another major problem for TMD-based transistors.

### BRIEF DESCRIPTION OF THE DRAWINGS

FIGS. 1A-1D depict illustrative schematic diagrams for direct ion modification of 2D material for enhanced contact resistance, in accordance with one or more example embodiments of the present disclosure.

FIGS. 2A-2E depict illustrative schematic diagrams for scalable direct ion modification of 2D material with patterned ion blocking mask, in accordance with one or more example embodiments of the present disclosure.

FIGS. 3A-3C depict illustrative schematic diagrams for direct ion modification of 2D material through contact metal for enhanced TMD-Metal contact resistance, in accordance with one or more example embodiments of the present disclosure.

FIG. 4 illustrates a flow diagram of a process for an illustrative ion beams fabrication system, in accordance with one or more example embodiments of the present disclosure.

Certain implementations will now be described more fully below with reference to the accompanying drawings, in which various implementations and/or aspects are shown. However, various aspects may be implemented in many different forms and should not be construed as limited to the implementations set forth herein; rather, these implementations are provided so that this disclosure will be thorough and complete, and will fully convey the scope of the disclosure to those skilled in the art. Like numbers in the figures refer to like elements throughout. Hence, if a feature is used across several drawings, the number used to identify the feature in the drawing where the feature first appeared will be used in later drawings.

### DETAILED DESCRIPTION

The following description and the drawings sufficiently illustrate specific embodiments to enable those skilled in the art to practice them. Other embodiments may incorporate structural, logical, electrical, process, algorithm, and other changes. Portions and features of some embodiments may be included in, or substituted for, those of other embodiments. Embodiments set forth in the claims encompass all available equivalents of those claims.

Various metals such as Indium (In) and Bismuth (Bi) that have very low melting temperatures were used to form low contact resistance with the TMDs, however these metals alone are not compatible with 300 millimeters (mm) line due to tool contamination issues. Thus, In and Bi metals are not fabrication compatible.

Example embodiments of the present disclosure relate to systems, methods, and devices for the fabrication of novel devices by tuning the electronic properties of 2D materials using ion beams. Examples of 2D material may include, but not limited to, Graphene family (e.g., Graphene, hBn, BCN, Fluorographene, Graphene Oxide, etc.), 2D Chalcogenides (e.g., MoS2, WS2, MoSe2, WSe2, Semiconducting dichalcogenides, Metal Dichalcogenides, Layered semiconductors, etc.), 2D oxides (Micas BSCCO, MoO3, WO3, Layered Cu oxides, TiO2, MnO2, V2O5, TaO3, RuO2, Perovskite-type, Hydroxides, etc.). The 2D materials may be monolayer or multi-layers.

In one embodiment, ion beams fabrication system may facilitate modification of the electronic structure of the 2D materials by creating vacancies, therefore, changing the stoichiometry (ratio or the elements-composition) of 2D materials locally by ion beam (with precise localization using both spatial resolution of ion beam, and tuning lateral and depth interaction ranges with ion energy). Some example of inert ion beams may include ion beams of helium, neon, nitrogen, oxygen, argon, xenon, etc. For example, helium and/or neon (hereinafter referred to as “He+/Ne+” or “He/Ne ion”) can be used to implant ions as well as create point defects in target materials with a high degree of precision. The site-selective defect generation and/or ion implantation can serve to functionalize materials. The precise tuning of optical, mechanical, and electronic properties in various materials have been demonstrated. He+/Ne+ or other ions can be used to create vacancies to induce low contact resistance with the metal contacts which is the major challenge for the implementation of the TMDs in field-effect transistor (FET). In this disclosure, helium and/or neon are used for illustrative purposes, but other types of ion beams may be used.

Ion beams such as He+/Ne+ can tune TMDs electronic properties by creating precision defects controlled by the ion beam energy and dose. Therefore, TMDs can be tuned n-type or p-type by ion impingement granting low contact resistance with the choice of metals compatible with fabrication.

The above descriptions are for purposes of illustration and are not meant to be limiting. Numerous other examples, configurations, processes, algorithms, etc., may exist, some of which are described in greater detail below. Example embodiments will now be described with reference to the accompanying figures.

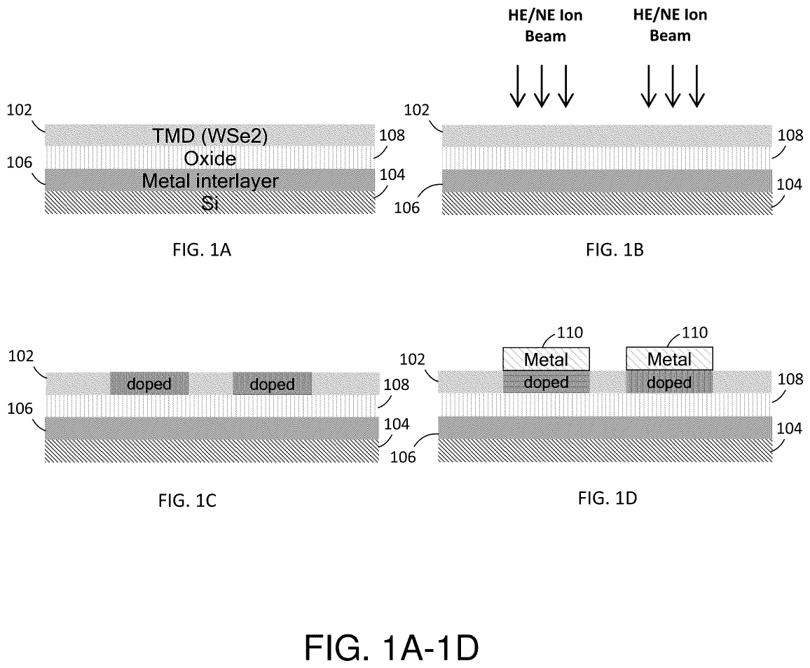

FIGS. 1A-1D depict illustrative schematic diagrams for direct ion modification of 2D material for enhanced contact resistance, in accordance with one or more example embodiments of the present disclosure.

Referring to FIG. 1A, there is shown a 2D material 102 (e.g., TMD) on a substrate that is comprised of a silicone layer 104, a metal interlayer 106, and an oxide layer 108. It should be understood that other layers may be included in the substrate.

Referring to FIG. 1B, there is shown the application of He and Ne ions. The ions would impinge the 2D material 102 to tune the 2D material 102 throughout by creating vacancies. This may be achieved by tuning the beam energy range and/or dose.

In one or more embodiments, the ion beam technology includes but is not limited to light element noble gas ion sources, plasma ion sources, and cold ion sources. The beam energy range or beam energy at specific layers/interfaces should be tunable over a large energy range (for instance from 1 to 100 keV) to achieve the desirable nanomachining, implantation, and lithography outcome.

Referring to FIG. 1C, there is shown the 2D material 102 having by vacancy formation using ion beams such as He and Ne ion beam (e.g., greater than 10-50 keV).

Referring to FIG. 1D, there shown the making of ohmic contact (low resistance) with an S/D metal 110 over the tuned (doped) 2D material 102. It should be understood that the use of the word doped in the figures indicates that the region is tuned based on the ion beam.

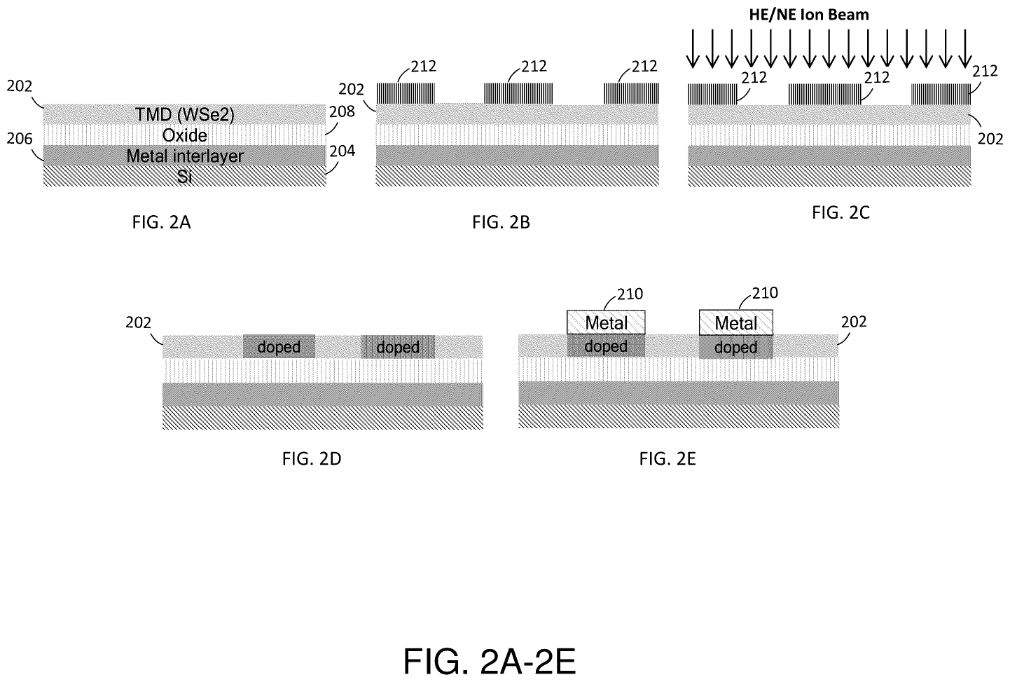

FIGS. 2A-2E depict illustrative schematic diagrams for scalable direct ion modification of 2D material with patterned ion blocking mask, in accordance with one or more example embodiments of the present disclosure.

Referring to FIG. 2A, there is shown a 2D material 202 (e.g., TMD) on a substrate that is comprised of a silicon layer 204, a metal interlayer 206, and an oxide layer 208.

Referring to FIG. 2B, there is shown ion stoppers 212 (e.g., oxide or nitride hard mask) placed on the 2D material 202 in order to block the ions from the He/Ne ion beam.

Referring to FIG. 2C, there is shown doping of the 2D material 202 by creating vacancies using He/Ne ion beam with the ion stoppers 212. In this case, the ion beam (e.g., helium, neon, nitrogen, oxygen, argon, xenon, etc.) may be applied over the entire surface such that the ions will be stopped when they hit the surface of the ion stoppers 212 but will hit the surface of the 2D material 202 where there are no ion stoppers 212.

Referring to FIG. 2D, there is shown the result of applying the ion beam (e.g., helium, neon, nitrogen, oxygen, argon, xenon, etc.) over the entire surface as performed in FIG. 2C. However, at this point, the ion stoppers 212 are removed. The outcome is that areas of the 2D material 202 that were exposed to the ion beam become tuned.

Referring to FIG. 2E, there is shown the making of ohmic contact with an S/D metal over the tuned (doped) 2D material 202.

It is understood that the above descriptions are for purposes of illustration and are not meant to be limiting.

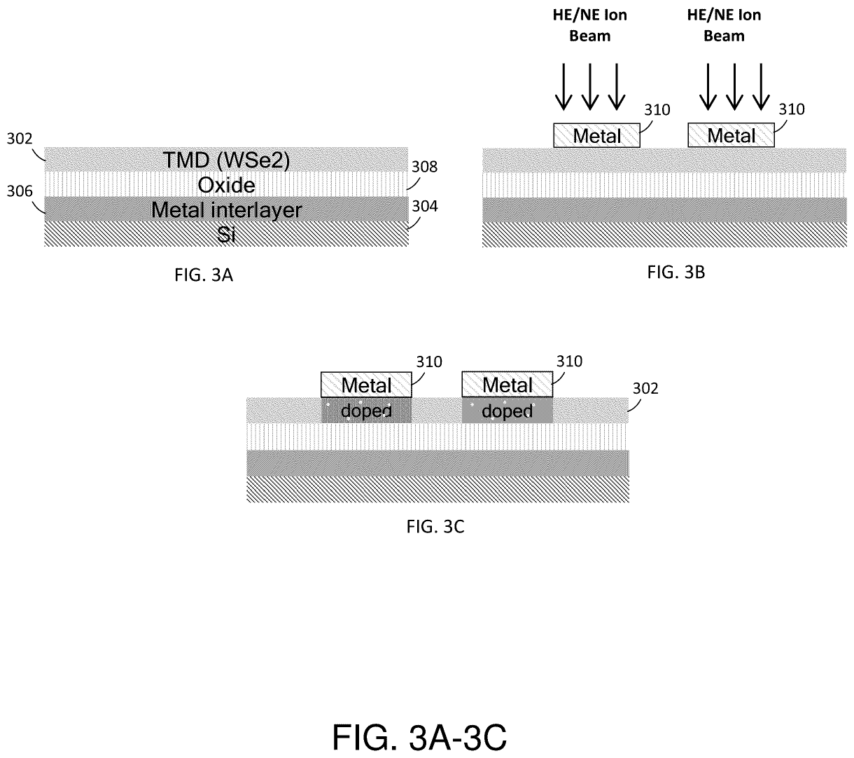

FIGS. 3A-3C depict illustrative schematic diagrams for direct ion modification of 2D material through contact metal for enhanced TMD-Metal contact resistance, in accordance with one or more example embodiments of the present disclosure.

Referring to FIG. 3A, there is shown a 2D material 302 (e.g., TMD) on a substrate that is comprised of a silicone layer 304, a metal interlayer 306, and an oxide layer 308.

Referring to FIG. 3B, there is shown He/Ne ions impinging on S/D metal 310 to tune (alter material properties such as tuning its electronic parameters) the 2D material (by creating defects or introducing metal atoms in 2D lattice by means of ions) 302 underneath the S/D metal 310. This helps to create a bond (electrical and physical contact) between the 2D material 310 and the S/D metal 310. It should be understood that He/Ne ions are shown for illustrative purposes, but other type of ions may be used (e.g., nitrogen, oxygen, argon, xenon, etc.).

Referring to FIG. 3C, there is shown doping of the 2D material 302 by vacancy creation in the 2D material 302 or metal ion migration into the 2D material 302 forming low contact resistance with S/D metal 310.

It is understood that the above descriptions are for purposes of illustration and are not meant to be limiting.

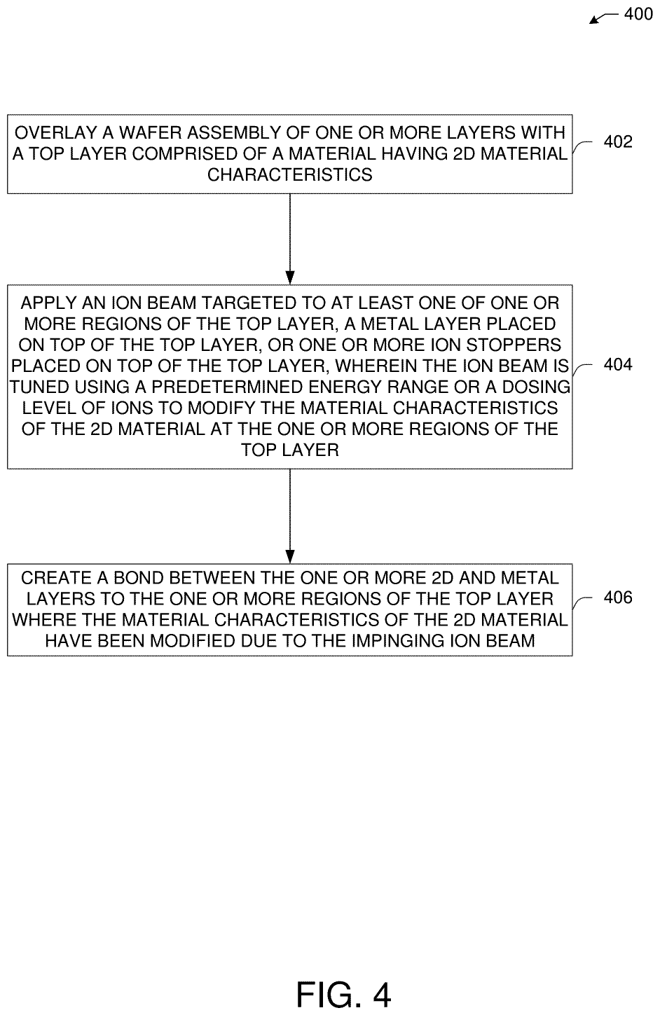

FIG. 4 illustrates a flow diagram of a process 400 for an ion beams fabrication system, in accordance with one or more example embodiments of the present disclosure.

At block 402, a device may overlay a wafer assembly of one or more layers with a top layer comprised of a 2D material.

At block 404, the device may apply an ion beam targeted to one or more regions of the top layer.

At block 406, the device may bond a metal layer to the one or more regions of the top layer targeted by the ion beam.

In one or more embodiments, the device may generate tuned regions on the top layer based on the applied ion beam.

In one or more embodiments, the device may have a hard mask on top of the top layer. Applying the hard mask on top of the top layer may prevent the ion beam from hitting the top layer of 2D material based on a predetermined pattern. The exposed regions of the top layer may be hit by the ion beam to generate the tuned regions. The ion beam passes through the metal layer placed over the one or more regions of the top layer to cause the tuned regions in the top layer. The ion beam passing through the metal layer causes the metal layer to bond to the top layer over the tuned regions. The one or more layers of the wafer assembly comprise an oxide layer, a metal layer, or a silicon layer. The hard mask is an oxide or a nitrite hard mask. The ion beam may be a helium ion beam, neon ion beam, nitrogen ion beam, oxygen ion beam, argon ion beam, xenon ion beam, etc. The top layer may comprise a transition metal dichalcogenide (TMD) layer and the 2D material comprises Graphene, 2D chalcogenide, or 2D oxide.

It is understood that the above descriptions are for purposes of illustration and are not meant to be limiting.

The word “exemplary” is used herein to mean “serving as an example, instance, or illustration.” Any embodiment described herein as “exemplary” is not necessarily to be construed as preferred or advantageous over other embodiments.

As used herein, unless otherwise specified, the use of the ordinal adjectives “first,” “second,” “third,” etc., to describe a common object, merely indicates that different instances of like objects are being referred to and are not intended to imply that the objects so described must be in a given sequence, either temporally, spatially, in ranking, or in any other manner.

A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions. One general aspect includes a method for fabricating a semiconductor package. The method also includes overlaying a wafer assembly of one or more layers with a top layer may include of a material having 2d material characteristics. The method also includes applying an ion beam targeted to at least one of one or more regions of the top layer, a metal layer placed on top of the top layer, or one or more ion stoppers placed on top of the top layer, where the ion beam is tuned using a predetermined energy range or a dosing level of ions to modify the material characteristics of the 2d material at the one or more regions of the top layer. The method also includes creating a bond between the one or more 2d and metal layers to the one or more regions of the top layer where the material characteristics of the 2d material have been modified due to the impinging ion beam. Other embodiments of this aspect include corresponding computer systems, apparatus, and computer programs recorded on one or more computer storage devices, each configured to perform the actions of the methods.

Implementations may include one or more of the following features. The method may include generate tuned regions of the top layer based on the modified characteristics of the one or more regions. The mask is a patterning mask that prevents ion permeability, where the mask is placed on top of the top layer. Applying the patterning mask on top of the top layer prevents the ion beam from hitting the top layer based on a predetermined pattern. Exposed regions of the top layer are hit by the ion beam to generate the tuned regions. The ion beam passes through the metal layer placed over the one or more regions of the top layer to cause the tuned regions in the top layer. The ion beam passing through the metal layer causes the metal layer to bond to the top layer over the tuned regions. The one or more layers of the wafer assembly may include an oxide layer, a metal layer, or a silicon layer. The patterning mask is an oxide or a nitrite hard mask. The ion beam may include ion beams of helium, neon, nitrogen, oxygen, argon, or xenon. The 2d material may include at least one of transition metal dichalcogenide (tmd), graphene, hbn, bcn, fluorographene, graphene oxide, mos2, ws2, mose2, wse2, semiconducting dichalcogenides, metalic dichalcogenides, layered semiconductors, micas bscco, moo3, wo3, layered cu oxides, tio2, mno2, v2o5, tao3, ruo2, perovskite-type, or hydroxides. Implementations of the described techniques may include hardware, a method or process, or computer software on a computer-accessible medium.

One general aspect includes a system for fabricating a semiconductor package. The system also includes overlay a wafer assembly of one or more layers with a top layer may include of a material having 2d material characteristics. The system also includes apply an ion beam targeted to at least one of one or more regions of the top layer, a metal layer placed on top of the top layer, or one or more ion stoppers placed on top of the top layer, where the ion beam is tuned using a predetermined energy range or a dosing level of ions to modify the material characteristics of the 2d material at the one or more regions of the top layer. The system also includes create a bond between the one or more 2d and metal layers to the one or more regions of the top layer where the material characteristics of the 2d material have been modified due to the impinging ion beam. Other embodiments of this aspect include corresponding computer systems, apparatus, and computer programs recorded on one or more computer storage devices, each configured to perform the actions of the methods.

Implementations may include one or more of the following features. The system where the operations further may include generate tuned regions on the top layer based on the modified characteristics of the one or more regions. The mask is a patterning mask that prevents ion permeability, where the mask is placed on top of the top layer. Applying the patterning mask on top of the top layer prevents the ion beam from hitting the top layer based on a predetermined pattern. Exposed regions of the top layer are hit by the ion beam to generate the tuned regions. The one or more layers of the wafer assembly may include an oxide layer, a metal layer, or a silicon layer. Implementations of the described techniques may include hardware, a method or process, or computer software on a computer-accessible medium.

One general aspect includes a semiconductor fabrication device. The semiconductor fabrication device also includes overlay a wafer assembly of one or more layers with a top layer may include of a material having 2d material characteristics. The device also includes apply an ion beam targeted to at least one of one or more regions of the top layer, a metal layer placed on top of the top layer, or one or more ion stoppers placed on top of the top layer, where the ion beam is tuned using a predetermined energy range or a dosing level of ions to modify the material characteristics of the 2d material at the one or more regions of the top layer. The device also includes create a bond between the one or more 2d and metal layers to the one or more regions of the top layer where the material characteristics of the 2d material have been modified due to the impinging ion beam. Other embodiments of this aspect include corresponding computer systems, apparatus, and computer programs recorded on one or more computer storage devices, each configured to perform the actions of the methods.

Implementations may include one or more of the following features. The semiconductor fabrication device where the processing circuitry is further configured to generate tuned regions on the top layer based on the modified characteristics of the one or more regions. The mask is a patterning mask that prevents ion permeability, where the mask is placed on top of the top layer. Implementations of the described techniques may include hardware, a method or process, or computer software on a computer-accessible medium.

Embodiments according to the disclosure are in particular disclosed in the attached claims directed to a method, a storage medium, a device and a computer program product, wherein any feature mentioned in one claim category, e.g., method, can be claimed in another claim category, e.g., system, as well. The dependencies or references back in the attached claims are chosen for formal reasons only. However, any subject matter resulting from a deliberate reference back to any previous claims (in particular multiple dependencies) can be claimed as well, so that any combination of claims and the features thereof are disclosed and can be claimed regardless of the dependencies chosen in the attached claims. The subject-matter which can be claimed comprises not only the combinations of features as set out in the attached claims but also any other combination of features in the claims, wherein each feature mentioned in the claims can be combined with any other feature or combination of other features in the claims. Furthermore, any of the embodiments and features described or depicted herein can be claimed in a separate claim and/or in any combination with any embodiment or feature described or depicted herein or with any of the features of the attached claims.

The foregoing description of one or more implementations provides illustration and description but is not intended to be exhaustive or to limit the scope of embodiments to the precise form disclosed. Modifications and variations are possible in light of the above teachings or may be acquired from practice of various embodiments.

Certain aspects of the disclosure are described above with reference to block and flow diagrams of systems, methods, apparatuses, and/or computer program products according to various implementations. It will be understood that one or more blocks of the block diagrams and flow diagrams, and combinations of blocks in the block diagrams and the flow diagrams, respectively, may be implemented by computer-executable program instructions. Likewise, some blocks of the block diagrams and flow diagrams may not necessarily need to be performed in the order presented, or may not necessarily need to be performed at all, according to some implementations.

These computer-executable program instructions may be loaded onto a special-purpose computer or other particular machine, a processor, or other programmable data processing apparatus to produce a particular machine, such that the instructions that execute on the computer, processor, or other programmable data processing apparatus create means for implementing one or more functions specified in the flow diagram block or blocks. These computer program instructions may also be stored in a computer-readable storage media or memory that may direct a computer or other programmable data processing apparatus to function in a particular manner, such that the instructions stored in the computer-readable storage media produce an article of manufacture including instruction means that implement one or more functions specified in the flow diagram block or blocks. As an example, certain implementations may provide for a computer program product, comprising a computer-readable storage medium having a computer-readable program code or program instructions implemented therein, said computer-readable program code adapted to be executed to implement one or more functions specified in the flow diagram block or blocks. The computer program instructions may also be loaded onto a computer or other programmable data processing apparatus to cause a series of operational elements or steps to be performed on the computer or other programmable apparatus to produce a computer-implemented process such that the instructions that execute on the computer or other programmable apparatus provide elements or steps for implementing the functions specified in the flow diagram block or blocks.

Accordingly, blocks of the block diagrams and flow diagrams support combinations of means for performing the specified functions, combinations of elements or steps for performing the specified functions and program instruction means for performing the specified functions. It will also be understood that each block of the block diagrams and flow diagrams, and combinations of blocks in the block diagrams and flow diagrams, may be implemented by special-purpose, hardware-based computer systems that perform the specified functions, elements or steps, or combinations of special-purpose hardware and computer instructions.

Conditional language, such as, among others, “can,” “could,” “might,” or “may,” unless specifically stated otherwise, or otherwise understood within the context as used, is generally intended to convey that certain implementations could include, while other implementations do not include, certain features, elements, and/or operations. Thus, such conditional language is not generally intended to imply that features, elements, and/or operations are in any way required for one or more implementations or that one or more implementations necessarily include logic for deciding, with or without user input or prompting, whether these features, elements, and/or operations are included or are to be performed in any particular implementation.

Many modifications and other implementations of the disclosure set forth herein will be apparent having the benefit of the teachings presented in the foregoing descriptions and the associated drawings. Therefore, it is to be understood that the disclosure is not to be limited to the specific implementations disclosed and that modifications and other implementations are intended to be included within the scope of the appended claims. Although specific terms are employed herein, they are used in a generic and descriptive sense only and not for purposes of limitation.

What is claimed is:

1. A method for fabricating a semiconductor package comprising:
overlaying a wafer assembly of one or more layers with a top layer comprised of a material having 2D material characteristics;
applying an ion beam targeted to at least one of one or more regions of the top layer, a metal layer placed on top of the top layer, or one or more ion stoppers placed on top of the top layer, wherein the ion beam is tuned using a predetermined energy range or a dosing level of ions to modify the material characteristics of the 2D material at the one or more regions of the top layer; and
creating a bond between the one or more 2D and metal layers to the one or more regions of the top layer where the material characteristics of the 2D material have been modified due to the impinging ion beam.

2. The method of claim 1, further comprising generate tuned regions of the top layer based on the modified characteristics of the one or more regions.

3. The method of claim 1, wherein the mask is a patterning mask that prevents ion permeability, wherein the mask is placed on top of the top layer.

4. The method of claim 3, wherein applying the patterning mask on top of the top layer prevents the ion beam from hitting the top layer based on a predetermined pattern.

5. The method of claim 1, wherein exposed regions of the top layer are hit by the ion beam to generate the tuned regions.

6. The method of claim 1, wherein the ion beam passes through the metal layer placed over the one or more regions of the top layer to cause the tuned regions in the top layer.

7. The method of claim 1, wherein the ion beam passing through the metal layer causes the metal layer to bond to the top layer over the tuned regions.

8. The method of claim 1, wherein the one or more layers of the wafer assembly comprise an oxide layer, a metal layer, or a silicon layer.

9. The method of claim 1, wherein the patterning mask is an oxide or a nitrite hard mask.

10. The method of claim 1, wherein the ion beam comprises ion beams of helium, neon, nitrogen, oxygen, argon, or xenon.

11. The method of claim 1, wherein the 2D material comprises at least one of transition metal dichalcogenide (TMD), Graphene, hBn, BCN, Fluorographene, Graphene Oxide, MoS2, WS2, MoSe2, WSe2, Semiconducting dichalcogenides, Metalic Dichalcogenides, Layered semiconductors, Micas BSCCO, MoO3, WO3, Layered Cu oxides, TiO2, MnO2, V2O5, TaO3, RuO2, Perovskite-type, or Hydroxides.

12. A system for fabricating a semiconductor package, the system comprising computer-executable instructions to:
overlay a wafer assembly of one or more layers with a top layer comprised of a material having 2D material characteristics;
apply an ion beam targeted to at least one of one or more regions of the top layer, a metal layer placed on top of the top layer, or one or more ion stoppers placed on top of the top layer, wherein the ion beam is tuned using a predetermined energy range or a dosing level of ions to modify the material characteristics of the 2D material at the one or more regions of the top layer; and
create a bond between the one or more 2D and metal layers to the one or more regions of the top layer where the material characteristics of the 2D material have been modified due to the impinging ion beam.

13. The system of claim 12, wherein the operations further comprise generate tuned regions on the top layer based on the modified characteristics of the one or more regions.

14. The system of claim 12, wherein the mask is a patterning mask that prevents ion permeability, wherein the mask is placed on top of the top layer.

15. The system of claim 12, wherein applying the patterning mask on top of the top layer prevents the ion beam from hitting the top layer based on a predetermined pattern.

16. The system of claim 12, wherein exposed regions of the top layer are hit by the ion beam to generate the tuned regions.

17. The system of claim 12, wherein the one or more layers of the wafer assembly comprise an oxide layer, a metal layer, or a silicon layer.

18. A semiconductor fabrication device, the device comprising processing circuitry coupled to storage, the processing circuitry configured to:
overlay a wafer assembly of one or more layers with a top layer comprised of a material having 2D material characteristics;
apply an ion beam targeted to at least one of one or more regions of the top layer, a metal layer placed on top of the top layer, or one or more ion stoppers placed on top of the top layer, wherein the ion beam is tuned using a predetermined energy range or a dosing level of ions to modify the material characteristics of the 2D material at the one or more regions of the top layer; and
create a bond between the one or more 2D and metal layers to the one or more regions of the top layer where the material characteristics of the 2D material have been modified due to the impinging ion beam.

19. The semiconductor fabrication device of claim 18, wherein the processing circuitry is further configured to generate tuned regions on the top layer based on the modified characteristics of the one or more regions.

20. The semiconductor fabrication device of claim 18, wherein the mask is a patterning mask that prevents ion permeability, wherein the mask is placed on top of the top layer.
